(19) United States
(12) Patent Application Publication
(10) Pub. No.: US 2026/0173662 A1
(43) Pub. Date: Jun. 18, 2026

(54) DISPLAY PANEL, DISPLAY APPARATUS, AND PREPARATION METHOD FOR DISPLAY PANEL

(71) Applicant: Visionox Technology Inc., Kunshan (CN)

(72) Inventor: Peng QIN, Kunshan (CN)

(73) Assignee: Visionox Technology Inc., Kunshan (CN)

(21) Appl. No.: 19/406,801

(22) Filed: Dec. 2, 2025

(30) Foreign Application Priority Data
Dec. 13, 2024 (CN) 202411839294.7

(51) Int. Cl. H10K 59/122; H10K 59/12; H10K 59/80

(52) U.S. Cl. CPC H10K 59/122; H10K 59/1201; H10K 59/873

(57) ABSTRACT

The present application discloses a display panel, a display apparatus, and a preparation method for a display panel. The display panel includes a substrate, an isolation structure, a light-emitting layer, and a first encapsulation layer. The first encapsulation layer includes encapsulation portions configured to encapsulate light-emitting units. Orthogonal projections of adjacent encapsulation portions on the substrate overlap to form overlapping regions. The overlapping regions include a first region and a second region, and a width of the first region is different from a width of the second region, for example, the second region has a larger width, that is, adjacent encapsulation portions have a larger overlapping width in the second region.

### CROSS-REFERENCE TO RELATED APPLICATIONS

The present application claims priority to the Chinese Patent Application 202411839294.7, filed on Dec. 13, 2024, and the entire contents of the aforementioned application are hereby incorporated by reference in its entirety.

### FIELD

The present application relates to the field of display, and particularly to a display panel, a display apparatus, and a preparation method for a display panel.

### BACKGROUND

Organic light-emitting diodes (OLEDs) and flat panel display apparatuses based on technologies such as light-emitting diodes (LEDs) have been widely used in various consumer electronics such as mobile phones, televisions, notebook computers, and desktop computers, and predominate in display apparatuses thanks to their advantages such as high image quality, energy efficiency, slim design, and a wide range of applications.

During the preparation of conventional display panels, light-emitting pixel patterning is usually implemented by means of a fine metal mask (FMM). FMM technology is mature and has rich experience in mass production. However, FMM technology also has problems such as limited accuracy, high development costs, and long development cycle. Fine metal mask-free technology eliminates the limitations of conventional OLED processes on display size, resolution, and other screen performances, and has the advantages of high performance, full-size coverage, and agile delivery. Patents CN118251982A, CN115666161A, CN116648095A, CN117062489A, CN118678742A, CN118785761A, CN115224220A, CN118678729A, CN118660529A and CN118660589A describe contents related to the fine metal mask-free technology for reference.

However, the usage performance of conventional OLED display products needs to be improved.

### SUMMARY

Embodiments of the present application provide a display panel, a display apparatus, and a preparation method for a display panel, which are intended to improve the usage performance of OLED display products.

An embodiment of a first aspect of the present application provides a display panel. The display panel includes: a substrate; an isolation structure located on a side of the substrate, where the isolation structure encircles a plurality of isolation openings; a light-emitting layer located on a side of the substrate, the light-emitting layer including a plurality of light-emitting units corresponding to the isolation openings; and a first encapsulation layer located on a side of the light-emitting layer that faces away from the substrate, the first encapsulation layer including a plurality of encapsulation portions that cover the corresponding isolation openings and extend onto the isolation structure surrounding the isolation openings, where on the isolation structure between adjacent isolation openings, orthographic projections of at least some of adjacent encapsulation portions on the substrate overlap to form a plurality of overlapping regions, at least some of the overlapping regions having different widths.

An embodiment of a third aspect of the present application provides a display apparatus including a display panel of any one of the above implementations.

An embodiment of a fourth aspect of the present application provides a preparation method for a display panel. The method includes:
preparing an isolation structure on a substrate, where the isolation structure encircles a plurality of isolation openings;
preparing a light-emitting layer on the substrate, the light-emitting layer including a plurality of light-emitting units corresponding to the isolation openings; and
preparing a first encapsulation layer on a side of the light-emitting layer that faces away from the substrate, the first encapsulation layer including a plurality of encapsulation portions that cover the isolation openings and extend onto the isolation structure surrounding the isolation openings, where on the isolation structure between adjacent isolation openings, orthographic projections of at least some of adjacent encapsulation portions on the substrate overlap to form overlapping regions, the overlapping regions including a first region and a second region, a width of the first region being different from a width of the second region.

According to the display panel of the embodiment of the present application, the display panel includes the substrate, the isolation structure, the light-emitting layer, and the first encapsulation layer. When the light-emitting layer is prepared, the light-emitting layer has a large drop at an edge of the isolation structure, and is difficult to be continuous, resulting in breakage. The light-emitting layer breaks to form light-emitting units that are disconnected from each other and located within the isolation openings, thereby reducing crosstalk of carriers in the light-emitting layer, and improving the display effect of the display panel. In addition, the light-emitting unit may be prepared without the use of a precision mask, which can reduce the development and use of the precision mask and lower the preparation cost. The first encapsulation layer includes encapsulation portions configured to encapsulate the light-emitting units. Orthogonal projections of adjacent encapsulation portions on the substrate overlap to form overlapping regions. This can mitigate the problem of dark spots occurring in the display panel due to damage to the light-emitting units caused by likely intrusion of a chemical solution through a gap between the encapsulation portions during subsequent preparation processes, when the adjacent encapsulation portions are spaced apart from each other. The overlapping regions include a first region and a second region, and a width of the first region is different from a width of the second region, for example, the second region has a larger width, that is, adjacent encapsulation portions have a larger overlapping width in the second region. This extends the path for intrusion of a chemical solution during subsequent preparation processes, making it difficult for the chemical solution to intrude through the encapsulation portions, and further avoiding the problem of dark spots occurring in the display panel due to damage to the light-emitting units caused by the intrusion of the chemical solution, thereby improving the display effect and usage performance of the display panel.

### BRIEF DESCRIPTION OF THE DRAWINGS

Other features, objectives, and advantages of the present application will become more obvious upon reading the following detailed description of non-limiting embodiments with reference to the accompanying drawings, where identical or similar reference signs indicate identical or similar features and the drawings are not necessarily drawn to scale.

FIG. 1 is a schematic partial top view of a display panel according to an embodiment of the present application;

FIG. 2 is a schematic partial top view of a display panel according to another embodiment;

FIG. 3 is a partial sectional view of a display panel according to an embodiment of the present application;

FIG. 4 is a partial sectional view of a display panel according to another embodiment;

FIG. 5 is a partial sectional view of a display panel according to yet another embodiment;

FIG. 6 is a schematic partial top view of a display panel according to yet another embodiment;

FIG. 7 is a schematic partial top view of a display panel according to still yet another embodiment;

FIG. 8 is a partial sectional view of a display panel according to still yet another embodiment;

FIG. 9 is a partial sectional view of a display panel according to a further embodiment;

FIG. 10 is a partial sectional view of a display panel according to a further embodiment;

FIG. 11 is a partial sectional view of a display panel according to a further embodiment;

FIG. 12 is a flowchart of a preparation method for a display panel according to an embodiment of the present application.

### LIST OF REFERENCE SIGNS

10. Display panel; 11. First region; 12. Second region; 13. Third region; 14. Fourth region;
100. Substrate;
200. Isolation structure; 210. First layer; 220. Second layer; 230. Third layer; 240. Isolation opening;
300. Light-emitting layer; 310. Light-emitting unit; 311. First light-emitting unit; 312. Second light-emitting unit; 313. Third light-emitting unit; 320. First pixel column; 330. Second pixel column; 340. Redundant unit;
400. Second electrode layer; 410. Second electrode; 420. Redundant electrode;
500. First encapsulation layer; 510: Encapsulation portion; 511. First main portion; 512. Second main portion; 512a. First segment; 512b. Connection portion; 512c. Second segment; 513. Third main portion; 520. Gap; 521. First gap; 522. Second gap; 530. Second encapsulation layer; 540. Third encapsulation layer;
600. Pixel define layer; 610. Pixel defining portion; 620. Pixel opening; 630. First electrode;
X. First direction; and Y. Second direction.

### DETAILED DESCRIPTION OF THE EMBODIMENTS

Features and exemplary embodiments in various aspects of the present application will be described in detail below. In order to make the embodiments of the present application clearer, the present application will be further described in detail below with reference to the accompanying drawings and embodiments. It should be understood that the embodiments described herein are merely configured to explain the present application and are not configured to limit the present application. Embodiments of the present application may be implemented without some of these specific details. The following description of the embodiments is merely to provide a better understanding of the present application by illustrating examples of the present application.

It should be noted that, herein, relational terms such as “first” and “second” are only used to distinguish one entity or operation from another entity or operation, and do not necessarily require or imply that such an actual relationship or order exists between these entities or operations. Furthermore, the terms “comprises”, “includes” or any other variant thereof are intended to cover non-exclusive inclusion, and a process, method, object or equipment including a series of elements not only includes those elements, but further includes other elements not explicitly listed, or further includes elements inherent to such process, method, object or equipment. If no more limitations are made, an element limited by “including . . . ” does not exclude other identical elements existing in the process, the method, the article, or the device which includes the element.

It should be understood that in the description of the structure of a component, a layer or region referred as being located “above” or “over” another layer or region may be directly on the other layer or region, or there may be other layers or regions between the layer or region and the other layer or region. Moreover, if the component is turned over, the layer or region is located “below” or “under” the other layer or region.

The embodiments of the present application provide a display panel, a display apparatus, and a preparation method for a display panel. Various embodiments of the display panel, the display apparatus, and the preparation method for a display panel will be illustrated below with reference to the drawings.

The embodiments of the present application provide a display panel, which may be an organic light-emitting diode (OLED) display panel.

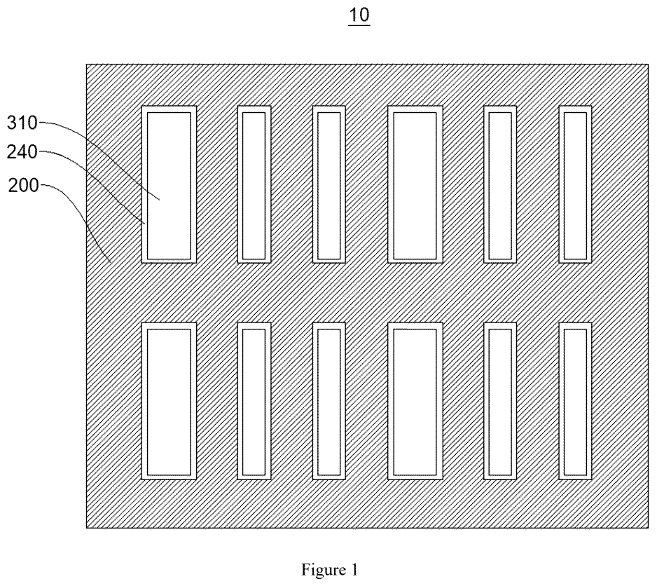

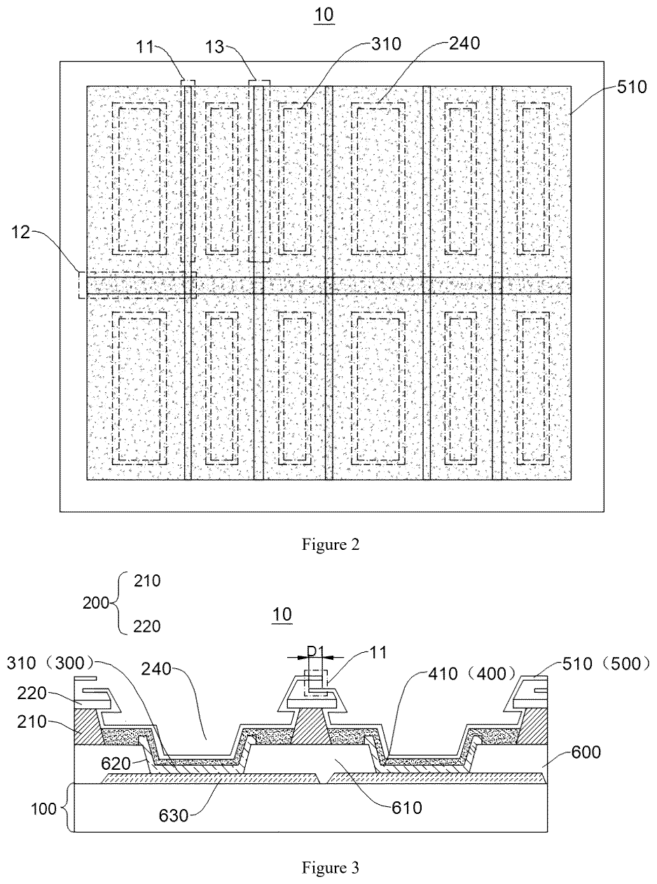

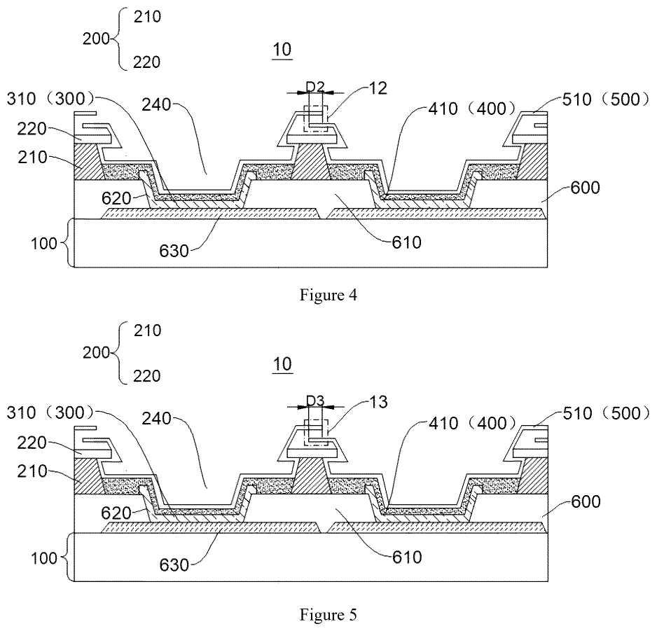

Referring to FIGS. 1 to 4 together, FIG. 1 is a schematic partial top view of a display panel according to an embodiment of the present application; FIG. 2 is a schematic partial top view of a display panel according to another embodiment; FIG. 3 is a partial sectional view of a display panel according to an embodiment of the present application; and FIG. 4 is a partial sectional view of a display panel according to another embodiment.

As shown in FIGS. 1 to 4, an embodiment of a first aspect of the present application provides a display panel 10. The display panel 10 includes: a substrate 100; an isolation structure 200 located on a side of the substrate 100, where the isolation structure 200 encircles a plurality of isolation openings 240; a light-emitting layer 300 located on a side of the substrate 100, the light-emitting layer 300 including a plurality of light-emitting units 310 corresponding to the isolation openings 240; and a first encapsulation layer 500 located on a side of the light-emitting layer 300 that faces away from the substrate 100, the first encapsulation layer 500 including a plurality of encapsulation portions 510 that cover the isolation openings 240 and extend onto the isolation structure 200 surrounding the isolation openings 240, where on the isolation structure 200 between adjacent isolation openings 240, orthographic projections of at least some of adjacent encapsulation portions 510 on the substrate 100 overlap to form overlapping regions, the overlapping regions including a first region 11 and a second region 12, a width D1 of the first region 11 being different from a width D2 of the second region 12.

The width of the first region 11 is a dimension of the first region 11 in a direction from the isolation opening 240 to its adjacent isolation opening 240, and the width of the second region 12 is a dimension of the second region 12 in a direction from the isolation opening 240 to its adjacent isolation opening 240. An extension direction of the first region 11 is perpendicular to the direction from the isolation opening 240 to its adjacent isolation opening 240, and an extension direction of the second region 12 is perpendicular to the direction from the isolation opening 240 to its adjacent isolation opening 240.

According to the display panel 10 of the embodiment of the present application, the display panel 10 includes the substrate 100, the isolation structure 200, the light-emitting layer 300, and the first encapsulation layer 500. When the light-emitting layer 300 is prepared, the light-emitting layer 300 has a large drop at an edge of the isolation structure 200, and is difficult to be continuous, resulting in breakage. The light-emitting layer 300 breaks to form light-emitting units 310 that are disconnected from each other and located within the isolation openings 240, thereby reducing crosstalk of carriers in the light-emitting layer 300, and improving the display effect of the display panel 10. In addition, the light-emitting units 310 may be prepared without the use of a precision mask, which can reduce the development and use of the precision mask and lower the preparation cost. The first encapsulation layer 500 includes encapsulation portions 510. The encapsulation portions 510 are configured to encapsulate the light-emitting units 310. Orthographic projections of adjacent encapsulation portions 510 on the substrate 100 overlap to form overlapping regions. This can mitigate the problem of dark spots occurring in the display panel 10 due to damage to the light-emitting units 310 caused by likely intrusion of a chemical solution through a gap between the encapsulation portions 510 during subsequent preparation processes, when the adjacent encapsulation portions 510 are spaced apart from each other. The overlapping regions include a first region 11 and a second region 12, and a width of the first region 11 is different from a width of the second region 12, for example, the second region 12 has a larger width, that is, adjacent encapsulation portions 510 have a larger overlapping width in the second region 12. This extends the path for intrusion of a chemical solution during subsequent processes, making it difficult for the chemical solution to intrude through the encapsulation portions 510, and further avoiding the problem of dark spots occurring in the display panel 10 due to damage to the light-emitting units 310 caused by the intrusion of the chemical solution, thereby improving the display effect and usage performance of the display panel 10.

In some embodiments, orthographic projections of any two adjacent encapsulation portions 510 on the substrate 100 overlap.

In these embodiments, orthographic projections of any adjacent encapsulation portions 510 on the substrate 100 overlap to form overlapping regions, and there are no two encapsulation portions 510 that are spaced apart from each other. This can further mitigate the problem of dark spots occurring in the display panel 10 due to damage to the light-emitting units 310 caused by likely intrusion of a chemical solution through a gap between the encapsulation portions 510 during subsequent preparation processes, when the adjacent encapsulation portions 510 are spaced apart from each other.

In some embodiments, orthographic projections, on the substrate 100, of the encapsulation portions 510 corresponding to adjacent light-emitting units 310 of different colors overlap to form overlapping regions, different encapsulation portions 510 are provided correspondingly for the light-emitting units 310 of different colors, and the encapsulation portions 510 corresponding to the light-emitting units 310 of different colors overlap each other and have different overlapping widths. A larger overlapping width can extend the path for intrusion of a chemical solution, making it difficult for the chemical solution to intrude through the encapsulation portions 510, and further avoiding the problem of dark spots occurring in the display panel 10 due to damage to the light-emitting units 310 caused by the intrusion of the chemical solution, thereby improving the display effect and usage performance of the display panel 10.

In some embodiments, orthographic projections of adjacent light-emitting units 310 of the same color on the substrate 100 are within an orthographic projection of the same encapsulation portion 510 on the substrate 100.

In some embodiments, the light-emitting units 310 include a first group of light-emitting units 310 and a second group of light-emitting units 310. The first group of light-emitting units 310 includes two adjacent light-emitting units 310, and the second group of light-emitting units 310 includes two adjacent light-emitting units 310. The first region 11 is located between the two adjacent light-emitting units 310 in the first group of light-emitting units 310, and the second region 12 is located between the two adjacent light-emitting units 310 in the second group of light-emitting units 310, a width D1 of the first region 11 being less than a width D2 of the second region 12.

The two light-emitting units 310 in the first group of light-emitting units 310 and the two light-emitting units 310 in the second group of light-emitting units 310 are four different light-emitting units 310, or one of the two light-emitting units 310 in the first group of light-emitting units 310 is the same as one of the two light-emitting units 310 in the second group of light-emitting units 310.

The first region 11 being located between the two adjacent light-emitting units 310 in the first group of light-emitting units 310 means an orthographic projection of the first region 11 on the substrate 100 being between orthographic projections of the two adjacent light-emitting units 310 in the first group of light-emitting units 310 on the substrate 100. The second region 12 being located between the two adjacent light-emitting units 310 in the second group of light-emitting units 310 means an orthographic projection of the second region 12 on the substrate 100 being between orthographic projections of the two adjacent light-emitting units 310 in the second group of light-emitting units 310 on the substrate 100.

In these embodiments, the first region 11 and the second region 12 are respectively located between two different groups of light-emitting units 310, and the width of the first region 11 is less than the width of the second region 12, that is, the overlapping regions located between the two adjacent light-emitting units 310 in the first group of light-emitting units 310 have a larger width, and adjacent encapsulation portions 510 have a larger overlapping width therebetween. This extends the path for intrusion of a chemical solution during subsequent preparation processes, making it difficult for the chemical solution to intrude through the encapsulation portions 510, and further avoiding the problem of dark spots occurring in the display panel 10 due to damage to the light-emitting units 310 caused by the intrusion of the chemical solution.

Referring to FIGS. 2 to 5 together, FIG. 5 is a partial sectional view of a display panel according to yet another embodiment.

As shown in FIGS. 2 to 5, in some embodiments, the overlapping regions further include a third region 13, and the light-emitting units 310 further include a third group of light-emitting units 310. The third group of light-emitting units 310 includes two adjacent light-emitting units 310. The third region 13 is located between the two adjacent light-emitting units 310 in the third group of light-emitting units 310, a width D3 of the third region 13 being less than the width D2 of the second region 12.

In these embodiments, the second region 12 and the third region 13 are respectively located between two different groups of light-emitting units 310, and the width of the third region 13 is less than the width of the second region 12, that is, the overlapping regions located between the two adjacent light-emitting units 310 in the first group of light-emitting units 310 have a larger width, and adjacent encapsulation portions 510 have a larger overlapping width therebetween. This extends the path for intrusion of a chemical solution during subsequent processes, making it difficult for the chemical solution to intrude the encapsulation portions 510, and further avoiding the problem of dark spots occurring in the display panel 10 due to damage to the light-emitting units 310 caused by the intrusion of the chemical solution.

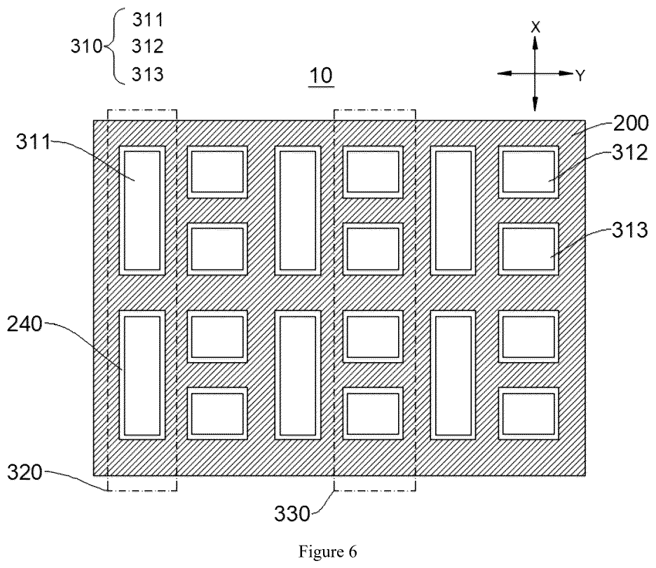

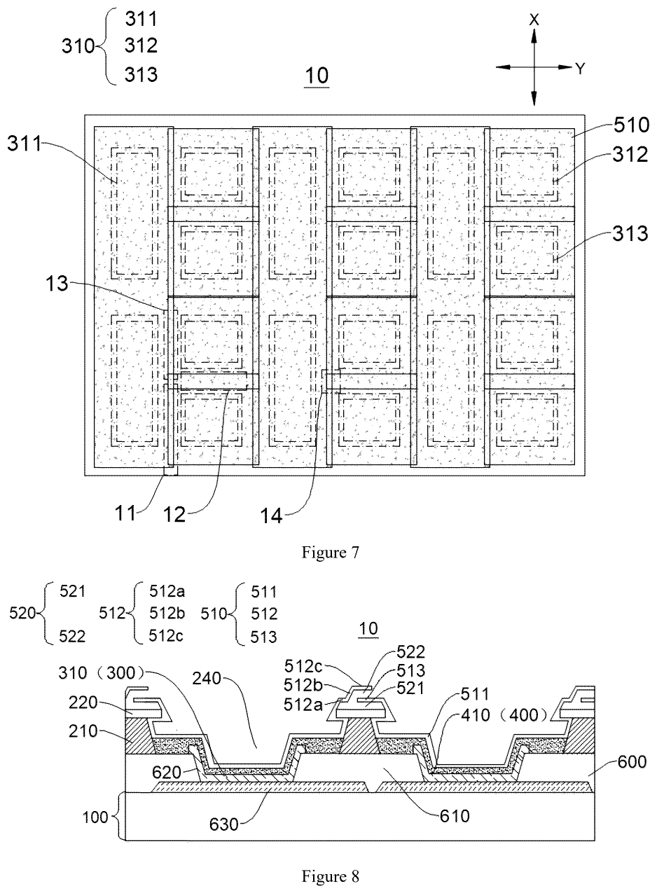

Referring to FIGS. 6 and 7 together, FIG. 6 is a schematic partial top view of a display panel according to yet another embodiment; and FIG. 7 is a schematic partial top view of a display panel according to still yet another embodiment.

As shown in FIGS. 6 and 7, in some embodiments, the light-emitting units 310 include a first light-emitting unit 311, a second light-emitting unit 312, and a third light-emitting unit 313. The first region 11 is located between the first light-emitting unit 311 and the second light-emitting unit 312 that are adjacent to each other, and the second region 12 is located between the second light-emitting unit 312 and the third light-emitting unit 313 that are adjacent to each other.

In these embodiments, the first region 11 is located between the first light-emitting unit 311 and the second light-emitting unit 312, and the second region 12 is located between the second light-emitting unit 312 and the third light-emitting unit 313. The width of the first region 11 is less than the width of the second region 12, that is, the overlapping regions located between the second light-emitting unit 312 and the third light-emitting unit 313 that are adjacent to each other have a larger width, and the encapsulation portions 510 corresponding to the second light-emitting unit 312 and the third light-emitting unit 313 that are adjacent to each other have a larger overlapping width therebetween. This extends the path for intrusion of a chemical solution during subsequent processes, making it difficult for the chemical solution to intrude the encapsulation portions 510, and further avoiding the problem of dark spots occurring in the display panel 10 due to damage to the light-emitting units 310 caused by the intrusion of the chemical solution.

In some embodiments, the overlapping regions further include a third region 13 located between the first light-emitting unit 311 and the third light-emitting unit 313, a width of the third region 13 being less than or equal to the width of the second region 12.

In these embodiments, the width of the third region 13 is less than the width of the second region 12, that is, the overlapping regions located between the second light-emitting unit 312 and the third light-emitting unit 313 that are adjacent to each other have a larger width, and adjacent encapsulation portions 510 have a larger overlapping width therebetween. This extends the path for intrusion of a chemical solution during subsequent processes, making it difficult for the chemical solution to intrude the encapsulation portions 510, and further avoiding the problem of dark spots occurring in the display panel 10 due to damage to the light-emitting units 310 caused by the intrusion of the chemical solution. When the width of the third region 13 is equal to the width of the second region 12, the width of each of the third region 13 and the second region 12 is greater than the width of the first region 11, that is, the third region 13 still has a larger width, and the encapsulation portions 510 corresponding to the first light-emitting unit 311 and the third light-emitting unit 313 that are adjacent to each other have a larger overlapping width therebetween. This extends the path for intrusion of a chemical solution during subsequent processes, making it difficult for the chemical solution to intrude the encapsulation portions 510, and further avoiding the problem of dark spots occurring in the display panel 10 due to damage to the light-emitting units 310 caused by the intrusion of the chemical solution.

In some embodiments, the width of the third region 13 is greater than or equal to the width of the first region 11.

In these embodiments, the width of the third region 13 is greater than the width of the first region 11, that is, the third region 13 still has a larger width, and the encapsulation portions 510 corresponding to the first light-emitting unit 311 and the third light-emitting unit 313 that are adjacent to each other have a larger overlapping width therebetween. This extends the path for intrusion of a chemical solution during subsequent processes, making it difficult for the chemical solution to intrude the encapsulation portions 510, and further avoiding the problem of dark spots occurring in the display panel 10 due to damage to the light-emitting units 310 caused by the intrusion of the chemical solution.

In some embodiments, the overlapping regions further include a fourth region 14, and in the fourth region 14, orthographic projections of at least three encapsulation portions 510 on the substrate 100 overlap.

In these embodiments, when the orthographic projections of the at least three encapsulation portions 510 on the substrate 100 overlap, a plurality of layers of encapsulation portions 510 are formed to overlap in the fourth region 14. This makes it more difficult for the chemical solution to intrude through the fourth region 14 in subsequent preparation processes, and further avoids the problem of dark spots occurring in the display panel 10 due to damage to the light-emitting units 310 caused by the intrusion of the chemical solution.

In some embodiments, in the fourth region 14, orthographic projections, on the substrate 100, of the encapsulation portions 510 corresponding to at least one first light-emitting unit 311, at least one second light-emitting unit 312, and at least one third light-emitting unit 313 overlap to form at least three layers of encapsulation portions 510 whose orthographic projections on the substrate 100 overlap.

In some embodiments, a plurality of first light-emitting units 311 are arranged into a first pixel column 320 along a first direction X, second light-emitting units 312 and third light-emitting units 313 are alternately arranged into a second pixel column 330 along the first direction X, and the first pixel column 320 and the second pixel column 330 are alternately arranged along a second direction Y, the first direction X intersecting the second direction Y. The arrangement of the light-emitting units 310 into the first pixel column 320 and the second pixel column 330 is relatively uniform, thereby improving the display effect of the display panel 10.

In some embodiments, the first light-emitting unit 311 is a blue light-emitting unit 310, the second light-emitting unit 312 is a red light-emitting unit 310, and the third light-emitting unit 313 is a green light-emitting unit 310.

In some embodiments, the first light-emitting unit 311, the second light-emitting unit 312, and the third light-emitting unit 313 are arranged side by side along the second direction Y, and the first light-emitting unit 311, the second light-emitting unit 312, and the third light-emitting unit 313 are arranged more uniformly, thereby improving the display effect of the display panel 10.

In some embodiments, the first region 11 is located between the first light-emitting unit 311 and the second light-emitting unit 312 that are adjacent to each other, the second region 12 is located between the second light-emitting unit 312 and the third light-emitting unit 313 that are adjacent to each other, and the third region 13 is located between the first light-emitting unit 311 and the third light-emitting unit 313. The first region 11, the second region 12, and the third region 13 are located on a side of the same first light-emitting unit 311 that is in the second direction Y.

In some embodiments, an orthographic projection of at least part of the encapsulation portions 510 on the substrate 100 is provided with a chamfer at the edge of the orthographic projection, to avoid overlapping with orthographic projections of other multiple layers of already overlapping encapsulation portions 510 on the substrate 100. For example, the encapsulation portions 510 corresponding to the first light-emitting unit 311 and the second light-emitting unit 312 overlap each other, and the encapsulation portion 510 corresponding to the third light-emitting unit 313 is provided with a chamfer at a diagonal position where the encapsulation portion 510 corresponding to the third light-emitting unit 313 is close to the first light-emitting unit 311 and the second light-emitting unit 312, and at this position, only the encapsulation portions 510 corresponding to the first light-emitting unit 311 and the second light-emitting unit 312 overlap each other, and they do not overlap the encapsulation portion 510 corresponding to the third light-emitting unit 313. This can mitigate the problem of a reduced encapsulation reliability due to multi-layer overlapping.

Referring to FIG. 8, FIG. 8 is a partial sectional view of a display panel according to still yet another embodiment.

As shown in FIG. 8, in some embodiments, the encapsulation portion 510 includes a first main portion 511 located within the isolation opening 240, and a second main portion 512 and a third main portion 513 that are connected to the first main portion 511 and located on a side of the isolation structure 200 that faces away from the substrate 100. The second main portion 512 and the third main portion 513 are located on a peripheral side of the first main portion 511. The second main portion 512 includes a first segment 512a, a connection portion 512b, and a second segment 512c. The first segment 512a is connected to the first main portion 511, the connection portion 512b is connected between the first segment 512a and the second segment 512c. An orthographic projection of the second segment 512c of one of two adjacent encapsulation portions 510 on the substrate 100 overlaps with the third main portion 513 of the other one of the two adjacent encapsulation portions to form the overlapping region.

The second main portion 512 and the third main portion 513 being located on the peripheral side of the first main portion 511 means in the same encapsulation portion 510, the second main portion 512 and the third main portion 513 being located on two sides of the first main portion 511 in the same direction, or in the same encapsulation portion 510, the second main portion 512 being located on a side of the first main portion 511 that is in a first direction X, and the third main portion 513 being located on a side of the first main portion 511 that is in a second direction Y.

In these embodiments, the orthographic projection of the second segment 512c of one of the two adjacent encapsulation portions 510 on the substrate 100 overlaps with the third main portion 513 of the other one of the two adjacent encapsulation portions to form the overlapping regions, which can extend the path for intrusion of a chemical solution, making it difficult for the chemical solution to intrude from the location of the second segment 512c and the third main portion 513 and along the first main portion 511, and avoiding the problem of dark spots occurring in the display panel 10 due to damage to the light-emitting units 310 caused by the intrusion of the chemical solution, thereby improving the display effect and usage performance of the display panel 10.

In some embodiments, the second segment 512c is located on a side of the third main portion 513 that faces away from the substrate 100.

In some embodiments, the second main portion 512, the third main portion 513, and the isolation structure 200 are spaced apart from each other to form a gap 520. The second main portion 512 and the isolation structure 200 are spaced apart from each other to form the gap 520, the third main portion 513 and the isolation structure 200 are spaced apart from each other to form the gap 520, and the second main portion 512 and the third main portion 513 are spaced apart from each other to form the gap 520, and adjacent encapsulation portions 510 are separated from and are not in contact with each other in a thickness direction, reducing mutual influence between the encapsulation portions 510, and preventing the occurrence of warping and other defects in the encapsulation portion 510 from causing the same problem in other encapsulation portions 510.

In some embodiments, the encapsulation portion 510 includes a first main portion 511 located within the isolation opening 240 and a second main portion 512 located on a side of the isolation opening 240 that faces away from the substrate 100, a width of part of the second main portion 512 of the encapsulation portion 510 that is in the first region 11 being less than a width of part of the second main portion of the same encapsulation portion that is in the second region 12. The width of the part of the second main portion 512 of the encapsulation portion 510 that is in the first region 11 being less than the width of the part of the second main portion of the same encapsulation portion that is in the second region 12 indicates that the second main portion 512 has a larger width in the second region 12. This extends the path for intrusion of a chemical solution during subsequent processes, making it difficult for the chemical solution to intrude the encapsulation portions 510, and further avoiding the problem of dark spots occurring in the display panel 10 due to damage to the light-emitting units 310 caused by the intrusion of the chemical solution.

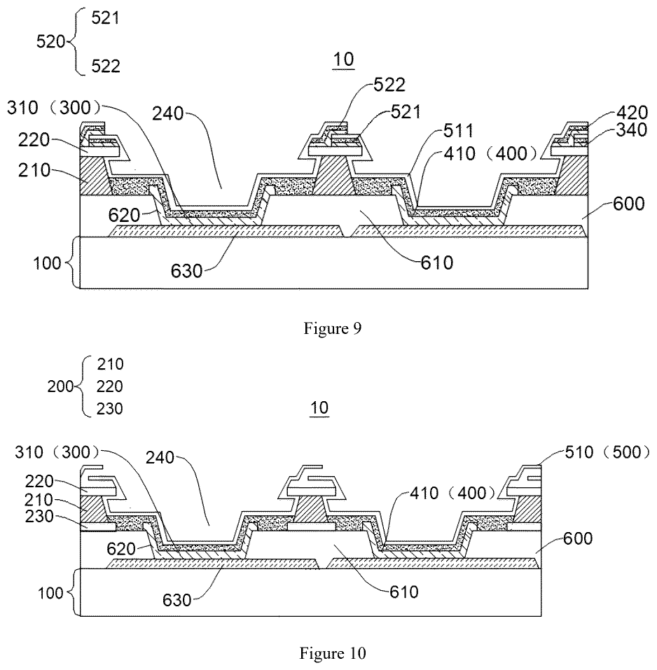

Referring to FIG. 9, FIG. 9 is a partial sectional view of a display panel according to a still further embodiment.

As shown in FIG. 9, In some embodiments, the light-emitting layer 300 further includes a redundant unit 340. The redundant unit 340 is located within the gap 520.

In these embodiments, when the light-emitting layer 300 is prepared, at least part of the light-emitting layer 300 that is located within the gap 520 is reserved to form the redundant unit 340 located within the gap 520, which can reduce preparation processes and simplify process steps. In addition, the redundant unit 340 is provided within the gap 520, which can block a chemical solution in subsequent preparation processes, and further avoid the problem of dark spots occurring in the display panel 10 due to damage to the light-emitting units 310 caused by the intrusion of the chemical solution through the gap 520.

In some embodiments, the gap 520 includes a first gap 521 and a second gap 522. The first gap 521 is located between the first segment 512a and the isolation structure 200 and between the third main portion 513 and the isolation structure 200. The second gap 522 is located between the third main portion 513 and the second segment 512c.

In some embodiments, the redundant unit 340 is located at least within the first gap 521.

In some embodiments, the redundant unit 340 is located within the first gap 521 and the second gap 522.

In these embodiments, when the light-emitting layer 300 is prepared, at least part of the light-emitting layer 300 that is located within the first gap 521 is reserved to form the redundant unit 340 located within the first gap 521, which can reduce preparation processes and simplify process steps. In addition, the redundant unit 340 is provided within the first gap 521, which can block a chemical solution in subsequent preparation processes, and further avoid the problem of dark spots occurring in the display panel 10 due to damage to the light-emitting units 310 caused by the intrusion of the chemical solution through the encapsulation portion 510. The redundant unit 340 being located within the first gap 521 and the second gap 522 can further block the chemical solution in subsequent preparation processes, thereby preventing damage to the light-emitting units 310 caused by the intrusion of the chemical solution through the first gap 521 and the second gap 522.

In some embodiments, the display panel 10 further includes: a pixel define layer 600 located on a side of the substrate 100, the pixel define layer 600 including a pixel defining portion 610 and pixel openings 620 encircled by the pixel defining portion 610, the pixel openings 620 being in communication with the isolation openings 240.

In these embodiments, the pixel openings 620 encircled by the pixel defining portion 610 are configured to define a light-emitting region of the display panel 10. The pixel openings 620 are communicatively connected with the isolation openings 240, to minimize obstruction of the isolation structure 200 to the pixel openings 620 and ensure the light emission effect of the display panel 10.

In some embodiments, the display panel 10 further includes first electrodes 630. The first electrodes 630 are located between the substrate 100 and the pixel define layer 600. The first electrodes 630 are at least partially exposed from the pixel openings 620 to drive light emission of the light-emitting unit 310.

In some embodiments, the isolation structure 200 includes a first layer 210 and a second layer 220 located on a side of the first layer 210 that faces away from the substrate 100, an orthographic projection of the first layer 210 on the substrate 100 being within an orthographic projection of the second layer 220 on the substrate 100.

In these embodiments, the first layer 210 and the second layer 220 are stacked to form the isolation structure 200. An orthographic projection, on the substrate 100, of a side of the first layer 210 provided close to the substrate 100 that faces away from the substrate 100 is within the orthographic projection of the second layer 220 on the substrate 100, the area of the orthographic projection of the second layer 220 is greater than the area of the orthographic projection of the side of the first layer 210 that faces away from the substrate 100, and the second layer 220 covers the surface of the first layer 210 that is close to the second layer 220, in which case the first layer 210 is recessed relative to the second layer 220 in a direction away from the second isolation opening 240 and the first isolation opening 240. When the light-emitting layer 300 is prepared, the light-emitting layer 300 has a large drop at an edge of the isolation structure 200, and the first layer 210 is recessed relative to the second layer 220, which makes it difficult for the light-emitting layer 300 to be continuous at the edge of the isolation structure 200, resulting in breakage. The light-emitting layer 300 breaks to form light-emitting units 310 that are disconnected from each other. In all the embodiments of the present application, it is not required that the isolation structure 200 is an inverted trapezoidal structure or a two-layer structure. Any structure that can achieve a disconnection effect of the light-emitting layer 300 is acceptable.

In some embodiments, the first layer 210 includes a conductive material. For example, the first layer 210 includes a non-metallic conductive material or a metallic conductive material to realize an electrical connection between the isolation structure 200 and the second electrode 410.

In some embodiments, the second layer 220 includes a conductive material or an insulation material, where the insulation material may be at least one of silicon nitride or silicon oxide.

In these embodiments, the second layer 220 includes a conductive material, for example, the second layer 220 includes a non-metallic conductive material or a metallic conductive material. When the second layer 220 is made of a non-metallic conductive material or an insulation material, during wet etching of the first layer 210 with an etching solution, the second layer 220 is difficult to etch, thereby making it easier for the first layer 210 to be recessed relative to the second layer 220.

In some embodiments, the first layer 210 and the second layer 220 each include a metallic material, and the first layer 210 and the second layer 220 are made of different materials.

In these embodiments, when both the first layer 210 and the second layer 220 are made of the metallic material, the first layer 210 may be wet etched with an etching solution, and the etching solution is provided to enable an etching rate of the second layer 220 to be less than an etching rate of the first layer 210. Since the first layer 210 has a greater etching rate, when wet etching is performed with the etching solution, the first layer 210 is etched faster even though the second layer 220 is subjected to some etching, which causes the first layer 210 to be recessed relative to the second layer 220.

Referring to FIG. 10, FIG. 10 is a partial sectional view of a display panel according to a still further embodiment.

As shown in FIG. 10, in some embodiments, the isolation structure 200 further includes a third layer 230 located on a side of the first layer 210 that faces the substrate 100, an orthographic projection of the first layer 210 on the substrate 100 being within an orthographic projection of the third layer 230 on the substrate 100.

In these embodiments, a large amount of waste is generated during the etching of the first layer 210 and is likely to enter other locations of the display panel 10, thus causing an adverse effect. After the third layer 230 is provided, the first layer 210 may be better adhered to the third layer 230, and the generated etching waste falls on the third layer 230 to facilitate removal.

In some embodiments, the material of the second layer 220 is titanium (Ti) or molybdenum (Mo), the material of the first layer 210 is aluminum (Al), silver (Ag) or copper (Cu), and the material of the third layer 230 is titanium (Ti) or molybdenum (Mo). For example, the material of the isolation structure 200 is a three-layer metal composite material of Ti/Al/Ti (titanium/aluminum/titanium) or Ti/Al/Mo (titanium/aluminum/molybdenum).

The composition, preparation and the like of the isolation structure 200 are further described in patents CN118251982A, 202410864269.8, PCT/CN2024/098407, PCT/CN2024/102783, PCT/CN2024/098217, PCT/CN2024/099419, PCT/CN2024/099072, CN117979755A, CN117998900A, CN117062489A, CN117580403A, CN116583155A, CN116669477A, CN117396039A, CN116669480A, CN116600606A, CN117500332A for reference.

In some embodiments, the material of the first encapsulation layer 500 includes an inorganic material, which has good compactness and exhibits a good barrier property to water vapor and oxygen.

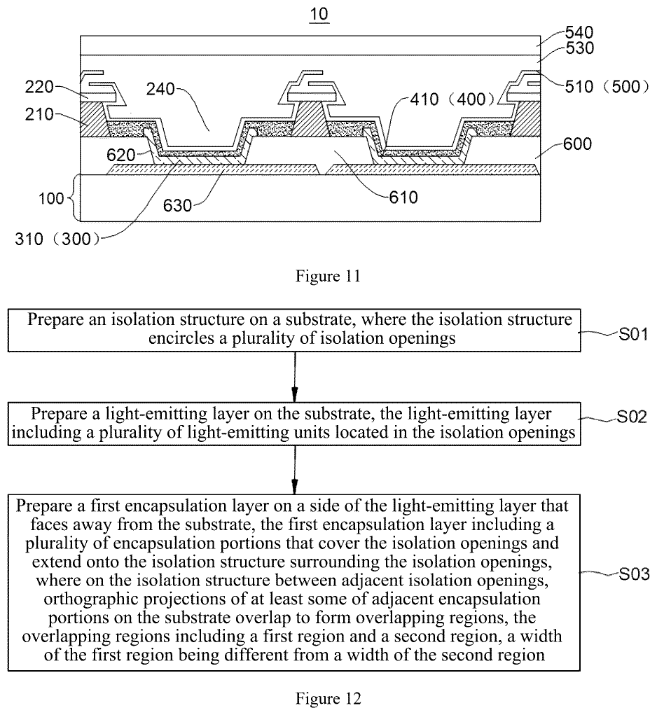

Referring to FIG. 11, FIG. 11 is a partial sectional view of a display panel according to a still further embodiment.

As shown in FIG. 11, In some embodiments, the display panel 10 further includes: a second encapsulation layer 530 located on a side of the first encapsulation layer 500 that faces away from the substrate 100; and a third encapsulation layer 540 located on a side of the second encapsulation layer 530 that faces away from the substrate 100. With three-layer encapsulation, the display panel 10 exhibits a good encapsulation performance and reduces the possibility of water vapor and oxygen intrusion.

In some embodiments, a material of the second encapsulation layer 530 includes an organic material.

In some embodiments, a material of the third encapsulation layer 540 includes an inorganic material. The first encapsulation layer 500, the second encapsulation layer 530, and the third encapsulation layer 540 are respectively encapsulated with an inorganic material, an organic material, and an inorganic material to form a thin film encapsulation (TFE) structure, which further improves the encapsulation performance.

In some embodiments, the display panel 10 further includes: a second electrode layer 400 located on a side of the light-emitting layer 300 that faces away from the substrate 100, the second electrode layer 400 including second electrodes 410 located within the isolation openings 240, the second electrodes 410 being electrically connected to the isolation structure 200.

In these embodiments, a plurality of second electrodes 410 are connected to each other through the isolation structure 200 to form a continuous electrode as an electrode of the light-emitting unit 310, to drive light emission of the light-emitting unit 310. One of the first electrode 630 and the second electrode 410 serves as an anode of the light-emitting unit 310, and the other serves as a cathode of the light-emitting unit 310. The embodiment of the present application is exemplified by taking the second electrode 410 as the cathode of the light-emitting unit 310, and the first electrode 630 as the anode of the light-emitting unit 310.

In some embodiments, the second electrode layer 400 includes redundant electrodes 420. The redundant electrodes 420 are located within the gap 520. The redundant electrodes 420 are located on a side of the redundant unit 340 that faces away from the substrate 100.

In some embodiments, an orthographic projection of each light-emitting unit 310 on the substrate 100 is within an orthographic projection of each second electrode 410 on the substrate 100.

In these embodiments, the orthographic projection of the light-emitting unit 310 on the substrate 100 is within the orthographic projection of the second electrode 410 on the substrate 100, that is, the second electrode 410 is disposed to cover the light-emitting unit 310 to serve as the electrode of the light-emitting unit 310 to ensure normal light emission of the light-emitting unit 310, thereby improving the display effect of the display panel 10.

In some embodiments, the light-emitting units 310 are spaced apart from the isolation structure 200, that is, the light-emitting units 310 are spaced apart from each other, thereby reducing crosstalk of carriers between the light-emitting units 310, and thus mitigating the problem of color cast in the light-emitting units 310.

In some embodiments, the light-emitting layer 300 includes an electron injection layer (EIL), an electron transport layer (ETL), a light-emitting material layer, a hole injection layer (HIL), and a hole transport layer (HTL).

As shown in FIGS. 1 to 11, an embodiment of a second aspect of the present application provides a display panel 10. The display panel 10 includes: a substrate 100; an isolation structure 200 located on a side of the substrate 100, where the isolation structure 200 encircles a plurality of isolation openings 240; a light-emitting layer 300 located on a side of the substrate 100, the light-emitting layer 300 including a plurality of light-emitting units 310 located within the isolation openings 240; and a first encapsulation layer 500 located on a side of the light-emitting layer 300 that faces away from the substrate 100, the first encapsulation layer 500 including a plurality of encapsulation portions 510 that cover the isolation openings 240 and extend onto the isolation structure 200 surrounding the isolation openings 240, where on the isolation structure 200 between adjacent isolation openings 240, orthographic projections of at least some of adjacent encapsulation portions 510 on the substrate 100 overlap to form overlapping regions, the overlapping regions including a first region 11 and a second region 12, a width of part of the encapsulation portion 510 that is in the first region 11 being different from a width of part of the same encapsulation portion that is in the second region 12.

In some embodiments, the encapsulation portion 510 includes a first main portion 511 located within the isolation opening 240 and a second main portion 512 located on a side of the isolation opening 240 that faces away from the substrate 100, a width of part of the second main portion 512 of the encapsulation portion 510 that is in the first region 11 being less than a width of part of the second main portion of the same encapsulation portion that is in the second region 12.

The same encapsulation portion 510 is an encapsulation portion 510 that is located corresponding to the same light-emitting unit 310 and covers the same isolation opening 240.

According to the display panel 10 of the embodiment of the present application, the display panel 10 includes the substrate 100, the isolation structure 200, the light-emitting layer 300, and the first encapsulation layer 500. When the light-emitting layer 300 is prepared, the light-emitting layer 300 has a large drop at an edge of the isolation structure 200, and is difficult to be continuous, resulting in breakage. The light-emitting layer 300 breaks to form light-emitting units 310 that are disconnected from each other and located within the isolation openings 240, thereby reducing crosstalk of carriers in the light-emitting layer 300, and improving the display effect of the display panel 10. In addition, the light-emitting units 310 may be prepared without the use of a precision mask, which can reduce the development and use of the precision mask and lower the preparation cost. The first encapsulation layer 500 includes encapsulation portions 510. The encapsulation portions 510 are configured to encapsulate the light-emitting units 310. Orthographic projections of adjacent encapsulation portions 510 on the substrate 100 overlap to form overlapping regions. This can mitigate the problem of dark spots occurring in the display panel 10 due to damage to the light-emitting units 310 caused by likely intrusion of a chemical solution through a gap between the encapsulation portions 510 during subsequent preparation processes, when the adjacent encapsulation portions 510 are spaced apart from each other. The overlapping regions include a first region 11 and a second region 12, and the width of the part of the second main portion 512 of the encapsulation portion 510 that is in the first region 11 is different from the width of the part of the second main portion of the same encapsulation portion that is in the second region 12, for example, the second main portion 512 has a larger width in the second region 12. This extends the path for intrusion of a chemical solution during subsequent preparation processes, making it difficult for the chemical solution to intrude through the encapsulation portion 510, thereby further avoiding the problem of dark spots occurring in the display panel 10 due to damage to the light-emitting units 310 caused by the intrusion of the chemical solution, and thus improving the display effect and usage performance of the display panel 10.

As for the structural design in this embodiment, it can be applied to other display panels 10, which can be selected according to actual situations, and this is not specifically limited in the present application.

An embodiment of a third aspect of the present application further provides a display apparatus including a display panel 10 of any one of the above embodiments of the first aspect and the second aspect. Since the display apparatus according to the embodiment of the third aspect of the present application includes the display panel 10 of any one of the above embodiments of the first aspect and the second aspect, the display apparatus according to the embodiment of the third aspect of the present application has the beneficial effects of the display panel 10 of any one of the above embodiments of the first aspect and the second aspect, which will not be described in detail here.

The display apparatus in the embodiment of the present application includes, but is not limited to, devices having a display function, such as a cell phone, a personal digital assistant (PDA), a tablet computer, an e-book reader, a television, an access control system, a smart fixed-line telephone, or a console.

Referring to FIGS. 1 to 12 together, FIG. 12 is a flowchart of a preparation method for a display panel according to an embodiment of the present application.

As shown in FIGS. 1 to 12, an embodiment of a fourth aspect of the present application provides a preparation method for a display panel 10. The method includes:
step S01: preparing an isolation structure 200 on a substrate 100, where the isolation structure 200 encircles a plurality of isolation openings 240;
step S02: preparing a light-emitting layer 300 on the substrate 100, the light-emitting layer 300 including a plurality of light-emitting units 310 located in the isolation openings 240; and
step S03: preparing a first encapsulation layer 500 on a side of the light-emitting layer 300 that faces away from the substrate 100, the first encapsulation layer 500 including a plurality of encapsulation portions 510 that cover the isolation openings 240 and extend onto the isolation structure 200 surrounding the isolation openings 240, where on the isolation structure 200 between adjacent isolation openings 240, orthographic projections of at least some of adjacent encapsulation portions 510 on the substrate 100 overlap to form overlapping regions, the overlapping regions including a first region 11 and a second region 12, a width of the first region 11 being different from a width of the second region 12.

In the preparation method for a display panel 10 according to the embodiment of the present application, the isolation structure 200 is prepared by step S01. The light-emitting layer 300 is prepared by step S02. When the light-emitting layer 300 is prepared, the light-emitting layer 300 has a large drop at an edge of the isolation structure 200, and is difficult to be continuous, resulting in breakage. The light-emitting layer 300 breaks to form light-emitting units 310 that are disconnected from each other and located within the isolation openings 240, thereby reducing crosstalk of carriers in the light-emitting layer 300, and improving the display effect of the display panel 10. In addition, the light-emitting units 310 may be prepared without the use of a precision mask, which can reduce the development and use of the precision mask and lower the preparation cost. The first encapsulation layer 500 is prepared by step S03. The first encapsulation layer 500 includes encapsulation portions 510. The encapsulation portions 510 are configured to encapsulate the light-emitting units 310. Orthographic projections of adjacent encapsulation portions 510 on the substrate 100 overlap to form overlapping regions. This can mitigate the problem of dark spots occurring in the display panel 10 due to damage to the light-emitting units 310 caused by likely intrusion of a chemical solution through a gap between the encapsulation portions 510 during subsequent preparation processes, when the adjacent encapsulation portions 510 are spaced apart from each other. The overlapping regions include a first region 11 and a second region 12, and a width of the first region 11 is different from a width of the second region 12, for example, the second region 12 has a larger width, that is, adjacent encapsulation portions 510 have a larger overlapping width in the second region 12. This extends the path for intrusion of a chemical solution during subsequent processes, making it difficult for the chemical solution to intrude through the encapsulation portions 510, and further avoiding the problem of dark spots occurring in the display panel 10 due to damage to the light-emitting units 310 caused by the intrusion of the chemical solution, thereby improving the display effect and usage performance of the display panel 10.

In some embodiments, the isolation openings 240 include a first isolation opening, a second isolation opening, and a third isolation opening. Step S02 includes:
preparing a first light-emitting material layer, a first electrode material layer, and a first encapsulation material layer on the substrate 100, and performing a patterning process on the first light-emitting material layer, the first electrode material layer, and the first encapsulation material layer to obtain a first light-emitting unit 311, a first sub-electrode, and a first encapsulation portion that are at least partially located within the first isolation opening;
preparing a second light-emitting material layer, a second electrode material layer, and a second encapsulation material layer on the substrate 100, and performing a patterning process on the second light-emitting material layer, the second electrode material layer, and the second encapsulation material layer to obtain a second light-emitting unit 312, a second sub-electrode, and a second encapsulation portion that are at least partially located within the second isolation opening; and
preparing a third light-emitting material layer, a third electrode material layer, and a third encapsulation material layer on the substrate 100, and performing a patterning process on the third light-emitting material layer, the third electrode material layer, and the third encapsulation material layer to obtain a third light-emitting unit 313, a third sub-electrode, and a third encapsulation portion that are at least partially located within the third isolation opening.

In these embodiments, the first light-emitting unit 311, the second light-emitting unit 312, and the third light-emitting unit 313 are prepared in order. The first encapsulation material layer, the second encapsulation material layer, and the third encapsulation material layer are subjected to the same or different instances of etching. In an exemplary arrangement, a plurality of first light-emitting units 311 are arranged into a first pixel column 320 along a first direction X, second light-emitting units 312 and third light-emitting units 313 are alternately arranged into a second pixel column 330 along the first direction X, and the first pixel column 320 and the second pixel column 330 are alternately arranged along a second direction Y, the first direction X intersecting the second direction Y. The part of the first encapsulation material layer in the first region 11 is subjected to one instance of etching, and the part of the second encapsulation material layer in the first region 11 is subjected to two instances of etching, that is, the encapsulation portion 510 located in the first region 11 is subjected to a total of three instances of etching; the part of the second encapsulation material layer in the second region 12 is subjected to one instance of etching, and the part of the third encapsulation material layer in the second region 12 is subjected to one instance of etching, that is, the encapsulation portion 510 located in the second region 12 is subjected to a total of two instances of etching; and the part of the first encapsulation material layer in the third region 13 is subjected to two instances of etching, and the part of the third encapsulation material layer in the third region 13 is subjected to one instance of etching, that is, the encapsulation portion 510 located in the third region 13 is subjected to a total of three instances of etching. Therefore, the encapsulation portion 510 in the second region 12 is subjected to fewer instances of etching, and the encapsulation portion 510 has a larger width. Therefore, the width of the second region 12 is greater than the width of the first region 11 and the width of the third region 13. The encapsulation portions 510 in the first region 11 and the third region 13 are subjected to the same instances of etching. Therefore, the width of the first region 11 is the same as or similar to the width of the third region 13.

In some embodiments, the first encapsulation material layer is etched using a dry etching process, including anisotropic dry etching and isotropic dry etching. The first encapsulation material layer is coated with a PR photoresist, where the part of the first encapsulation material layer that is coated with the PR photoresist is reserved during etching, and the part of the first encapsulation material layer that is exposed is etched away.

In some embodiments, the first electrode material layer is etched using a wet etching process. The first electrode material layer is coated with a PR photoresist, where the part of the first electrode material layer that is coated with the PR photoresist is reserved during etching, and the part of the first electrode material layer that is exposed is etched away.

In some embodiments, the first light-emitting material layer is etched using an ashing process. The first light-emitting material layer is coated with a PR photoresist, where the part of the first light-emitting material layer that is coated with the PR photoresist is reserved during etching, and the part of the first light-emitting material layer that is exposed is etched away.

When the first electrode material layer and the first light-emitting material layer are respectively etched using the wet etching process and the ashing process, the parts of the first electrode material layer and the first light-emitting material layer that are located on a side of the isolation structure 200 that faces away from the substrate 100 are etched away. Therefore, there is no redundant electrode 420 or redundant unit 340 within the gap 520 between the first encapsulation portion and the isolation structure 200.

In some embodiments, the first electrode material layer and the first light-emitting material layer are etched using the dry etching process.

When the first electrode material layer and the first light-emitting material layer are etched using the dry etching process, the parts of the first electrode material layer and the first light-emitting material layer that are located on a side of the isolation structure 200 that faces away from the substrate 100 are reserved. Therefore, there is a redundant electrode 420 and a redundant unit 340 within the gap 520 between the first encapsulation portion and the isolation structure 200.

In some embodiments, the second encapsulation material layer is etched using the dry etching process, including anisotropic dry etching and isotropic dry etching.

In some embodiments, the second electrode material layer is etched using the wet etching process.

In some embodiments, the second light-emitting material layer is etched using the ashing process.

When the second electrode material layer and the second light-emitting material layer are respectively etched using the wet etching process and the ashing process, the parts of the second electrode material layer and the second light-emitting material layer that are located on a side of the isolation structure 200 that faces away from the substrate 100 are etched away. Therefore, there is no redundant electrode 420 or redundant unit 340 within the gap 520 between the second encapsulation portion and the isolation structure 200.

In some embodiments, the second electrode material layer and the second light-emitting material layer are etched using the dry etching process.

When the second electrode material layer and the second light-emitting material layer are etched using the dry etching process, the parts of the second electrode material layer and the second light-emitting material layer that are located on a side of the isolation structure 200 that faces away from the substrate 100 are reserved. Therefore, there is a redundant electrode 420 and a redundant unit 340 within the gap 520 between the second encapsulation portion and the isolation structure 200.

In some embodiments, the third encapsulation material layer is etched using the dry etching process, including anisotropic dry etching.

In some embodiments, the third electrode material layer is etched using the wet etching process.

In some embodiments, the third light-emitting material layer is etched using the ashing process.

When the third electrode material layer and the third light-emitting material layer are respectively etched using the wet etching process and the ashing process, the parts of the third electrode material layer and the third light-emitting material layer that are located on a side of the isolation structure 200 that faces away from the substrate 100 are etched away. Therefore, there is no redundant electrode 420 or redundant unit 340 within the gap 520 between the third encapsulation portion and the isolation structure 200.

In some embodiments, the third electrode material layer and the third light-emitting material layer are etched using the dry etching process.

When the third electrode material layer and the third light-emitting material layer are etched using the dry etching process, the parts of the third electrode material layer and the third light-emitting material layer that are located on a side of the isolation structure 200 that faces away from the substrate 100 are reserved. Therefore, there is a redundant electrode 420 and a redundant unit 340 within the gap 520 between the third encapsulation portion and the isolation structure 200.

In some embodiments, the isolation openings 240 include a first isolation opening, a second isolation opening, and a third isolation opening. Step S02 includes:
preparing a first light-emitting material layer, a first electrode material layer, and a first encapsulation material layer on the substrate 100, and performing a patterning process on the first light-emitting material layer, the first electrode material layer, and the first encapsulation material layer, and the first light-emitting material layer, the first electrode material layer, and the first encapsulation material layer that are located within the first isolation opening and the second isolation opening are reserved;
preparing a second light-emitting material layer, a second electrode material layer, and a second encapsulation material layer on the substrate 100, and performing a patterning process on the second light-emitting material layer, the second electrode material layer, and the second encapsulation material layer, and the second light-emitting material layer, the second electrode material layer, and the second encapsulation material layer located within the first isolation opening and the third isolation opening are removed to obtain a second light-emitting unit 312, a second sub-electrode, and a second encapsulation portion that are at least partially located within the second isolation opening 240, and the first light-emitting material layer, the first electrode material layer, and the first encapsulation material layer located within the second isolation opening are removed to obtain a first light-emitting unit 311, a first sub-electrode, and a first encapsulation portion that are at least partially located within the first isolation opening; and
preparing a third light-emitting material layer, a third electrode material layer, and a third encapsulation material layer on the substrate 100, and performing a patterning process on the third light-emitting material layer, the third electrode material layer, and the third encapsulation material layer to obtain a third light-emitting unit 313, a third sub-electrode, and a third encapsulation portion that are at least partially located within the third isolation opening.

In these embodiments, the first light-emitting unit 311 and the second light-emitting unit 312 are prepared together. The first encapsulation material layer, the second encapsulation material layer, and the third encapsulation material layer are subjected to the same or different instances of etching. In an exemplary arrangement, a plurality of first light-emitting units 311 are arranged into a first pixel column 320 along a first direction X, second light-emitting units 312 and third light-emitting units 313 are alternately arranged into a second pixel column 330 along the first direction X, and the first pixel column 320 and the second pixel column 330 are alternately arranged along a second direction Y, the first direction X intersecting the second direction Y. The part of the first encapsulation material layer in the first region 11 is subjected to one instance of etching, and the part of the second encapsulation material layer in the first region 11 is subjected to two instances of etching, that is, the encapsulation portion 510 located in the first region 11 is subjected to a total of three instances of etching; the part of the second encapsulation material layer in the second region 12 is subjected to one instance of etching, and the part of the third encapsulation material layer in the second region 12 is subjected to one instance of etching, that is, the encapsulation portion 510 located in the second region 12 is subjected to a total of two instances of etching; and the part of the first encapsulation material layer in the third region 13 is subjected to one instance of etching, and the part of the third encapsulation material layer in the third region 13 is subjected to one instance of etching, that is, the encapsulation portion 510 located in the third region 13 is subjected to a total of two instances of etching. Therefore, the encapsulation portions 510 in the second region 12 and the third region 13 are subjected to fewer instances of etching, and the encapsulation portions 510 have a larger width. Therefore, the width of the second region 12 and the width of the third region 13 are each greater than the width of the first region 11. The encapsulation portions 510 in the second region 12 and the third region 13 are subjected to the same instances of etching. Therefore, the width of the second region 12 is the same as or similar to the width of the third region 13.

The embodiments of the present application as described above neither set forth all the details, nor do they limit the present application to only the described specific embodiments. Apparently, many modifications and variations can be made in light of the above description. The embodiments are selected and described in this specification to better explain the principles and practical applications of the present application, and good use of the present application can be made and modified and used in the present application. The present application is limited only by the claims and all the scopes and equivalents thereof.

What is claimed is:

1. A display panel, comprising:
a substrate;
an isolation structure located on a side of the substrate, wherein the isolation structure encircles a plurality of isolation openings;
a light-emitting layer located on a side of the substrate, the light-emitting layer comprising a plurality of light-emitting units corresponding to the isolation openings; and
a first encapsulation layer located on a side of the light-emitting layer facing away from the substrate, the first encapsulation layer comprising a plurality of encapsulation portions wherein the plurality of encapsulation portions cover the corresponding isolation openings and extend onto the isolation structure surrounding the isolation openings, wherein on the isolation structure between adjacent isolation openings, orthographic projections of at least some of adjacent encapsulation portions on the substrate overlap to form a plurality of overlapping regions, at least some of the overlapping regions having different widths.

2. The display panel according to claim 1, wherein orthographic projections of any two adjacent encapsulation portions on the substrate overlap.

3. The display panel according to claim 2, wherein orthographic projections, on the substrate, of the encapsulation portions corresponding to adjacent light-emitting units of different colors overlap to form the overlapping regions.

4. The display panel according to claim 2, wherein orthographic projections of adjacent light-emitting units of the same color on the substrate are within an orthographic projection of the same encapsulation portion on the substrate.

5. The display panel according to claim 1, wherein at least some of the plurality of encapsulation portions overlap in pairs to form a plurality of overlapping regions, the plurality of overlapping regions comprises a first region and a second region, a width of the first region is different from a width of the second region.

6. The display panel according to claim 5, wherein the overlapping regions further comprise a third region, a width of the third region is different from the width of the first region or the width of the second region.

7. The display panel according to claim 5, wherein the light-emitting units comprise a first light-emitting unit, a second light-emitting unit, and a third light-emitting unit, the first region is located between the first light-emitting unit and the second light-emitting unit adjacent to each other, and the second region is located between the second light-emitting unit and the third light-emitting unit adjacent to each other, the width of the first region is less than the width of the second region.

8. The display panel according to claim 6, wherein the light-emitting units comprise a first light-emitting unit, a second light-emitting unit, and a third light-emitting unit, the third region is located between the first light-emitting unit and the third light-emitting unit, a width of the third region is less than or equal to the width of the second region, and the width of the third region is less than or equal to the width of the first region.

9. The display panel according to claim 6, wherein the width of the third region is greater than or equal to the width of the first region.

10. The display panel according to claim 5, wherein the overlapping regions further comprise a fourth region, and in the fourth region, orthographic projections of at least three encapsulation portions on the substrate overlap.

11. The display panel according to claim 10, wherein the light-emitting units comprise a first light-emitting unit, a second light-emitting unit, and a third light-emitting unit, in the fourth region, orthographic projections, on the substrate, of the encapsulation portions corresponding to at least one first light-emitting unit, at least one second light-emitting unit, and at least one third light-emitting unit overlap.

12. The display panel according to claim 1, wherein the encapsulation portion comprises a first main portion located within the isolation opening, and a second main portion and a third main portion connected to the first main portion and located on a side of the isolation structure facing away from the substrate, the second main portion and the third main portion are located on a peripheral side of the first main portion, and the second main portion comprises a first segment, a connection portion, and a second segment, wherein the first segment is connected to the first main portion, the connection portion is connected between the first segment and the second segment, and an orthographic projection of the second segment of one of two adjacent encapsulation portions on the substrate overlaps with the third main portion of the other one of the two adjacent encapsulation portions to form the overlapping region.

13. The display panel according to claim 12, wherein the second main portion, the third main portion, and the isolation structure are spaced apart from each other to form a gap.

14. The display panel according to claim 13, wherein the light-emitting layer further comprises a redundant unit located within the gap.

15. The display panel according to claim 14, wherein the gap comprises a first gap and a second gap, the first gap is located between the first segment and the isolation structure and between the third main portion and the isolation structure, and the second gap is located between the third main portion and the second segment, and the redundant unit is at least located within the first gap.

16. The display panel according to claim 1, wherein the display panel further comprises:
a pixel define layer located on a side of the substrate, the pixel define layer comprising a pixel defining portion and pixel openings encircled by the pixel defining portion, the pixel openings being in communication with the isolation openings;
and the display panel further comprises first electrodes located between the substrate and the pixel define layer, the first electrodes being at least partially exposed from the pixel openings.

17. The display panel according to claim 1, wherein the isolation structure comprises a first layer and a second layer located on a side of the first layer that faces away from the substrate, an orthographic projection of the first layer on the substrate being within an orthographic projection of the second layer on the substrate.

18. The display panel according to claim 1, wherein a material of the first encapsulation layer comprises an inorganic material.

19. A preparation method for a display panel, comprising:
preparing an isolation structure on a substrate, wherein the isolation structure encircles a plurality of isolation openings;
preparing a light-emitting layer on the substrate, the light-emitting layer comprising a plurality of light-emitting units corresponding to the isolation openings; and
preparing a first encapsulation layer on a side of the light-emitting layer facing away from the substrate, the first encapsulation layer comprising a plurality of encapsulation portions covering the isolation openings and extend onto the isolation structure surrounding the isolation openings, wherein on the isolation structure between adjacent isolation openings, orthographic projections of at least some of adjacent encapsulation portions on the substrate overlap to form overlapping regions, the overlapping regions comprising a first region and a second region, a width of the first region being different from a width of the second region.
